(19) United States
(12) Patent Application Publication
(10) Pub. No.: US 2010/0231256 A1
(43) Pub. Date: Sep. 16, 2010

(54) SPARE CELL LIBRARY DESIGN FOR INTEGRATED CIRCUIT

(75) Inventors: Siddhartha Jain, Noida (IN); Gaurav Agarwal, Noida (IN); Ankit Desai, Noida (IN); Anurag Sharma, Noida (IN)

Correspondence Address: ONDA TECHNO Intl. Patent Attys., 12-1 Omiya-cho 2-chome, Gifu City, 500-8731, JP

(73) Assignee: FREESCALE SEMICONDUCTOR, INC, Austin, TX (US)

(21) Appl. No.: 12/400,849

(22) Filed: Mar. 10, 2009

(51) Int. Cl. H03K 19/177; H01L 21/82

(52) U.S. Cl. 326/41; 438/129; 257/E21.602

(57) ABSTRACT

A cell based design layout of an application specific integrated circuit (ASIC) having a function has reduceddecreased power leakage because functionally unconnected additional cells or spare cells of the integrated design layout are unconnected to the power supplies Vdd and Vss.

### BACKGROUND OF THE INVENTION

The present invention relates generally to a cell based application specific integrated circuit (ASIC) layout design and more particularly to reducing power consumption in an ASIC having a layout design with a spare cell or spare cell library layout design.

Traditional cell based ASIC layout designs typically include a base set of functional logic cells that are interconnected to perform the desired function of the ASIC. In particular, ASIC layout designs are common in very large scale integration (VLSI) of complex integrated circuits such as processors. In addition to the base set of functional logic cells, the ASIC layout designs typically comprise a plurality of spare cells that are randomly dispersed throughout the functional logic base set of cells. The spare cells may collectively form a spare cell library. The spare cells may be standard library cells. After a metallization process, the spare cells are not connected to the base set of functional logic cells nor do the spare cells form part of the functional logic of the ASIC.

The conventional spare cells are included in the ASIC design for the purpose of correcting, altering or changing the functionality of the ASIC during an engineering change order (ECO) process. Typically only a fraction of the spare cells are ever selected and connected to the functional base set of functional logic cells during the ECO process, which may occur before or after the metallization process. Once selected and interconnected during ECO to the base set of functional logic cells, the selected spare cells form part of the functionality of ASIC.

The spare cells may comprise a collection of different cells having different functions. Each spare cell typically includes at least one transistor and is pre-configured for a particular logic function. For example the cells may be arranged with logic cells as well as transistors, and each cell within the spare cell library typically comprises at least one logic gate such as inverters, NAND, NOR, flip-flops, and the like in PMOS or NMOS designs.

After metallization, often certain functional repairs, modifications and/or enhancements are required to be made to the ASIC to overcome any problems or shortcomings in the function of the ASIC. A conventional spare cell existing within the ASIC design may be selected as a spare cell that is used to realize the functional repairs, modifications and/or enhancements of the overall functional logic of the ASIC. Spare cells are selected from the spare cells existing within the ASIC design and may be used either before or after the ASIC has undergone metallization. New connections are made to interconnect between the existing base set of functional logic cells and selected spare cells of the spare cell library. Specific spare cells within the spare cells in the ASIC design are selected and arranged in a particular circuit configuration with metal interconnections during the ECO process to form part of the working functionality of the ASIC. The spare cells already exist in the ASIC layout design and the spare cells may come from a spare cell library or from the base library that are within the ASIC design. Inputs and outputs of the selected spare cells are configured accordingly to realize the required logic implementation. The selected spare cells are interconnected with the base set of functional logic cells in order to achieve the desired functionality in conjunction with the base set of functional logic cells of the ASIC for the desired repair, modification or enhancement of the ASIC.

Not all the spare cells are selected for interconnection with the base logic cells during ECO. The unselected spare cells are typically added to the ASIC design but are not used to realize the intended logic or working functionality of the ASIC. In all of the selected and unselected spare cells, the source of the PMOS and NMOS transistors are always connected to Vdd and Vss. This results in leakage through Vdd, Vss and the gate and adds to dissipated leakage power. With the ever increasing emphasis on reducing power, conventional cell libraries are power intensive. For example, as shown in the graph 100 of FIG. 6 a leakage trend of static power consumption per gate is shown at vt1 132, vt2 134, vt3 136, and vt4 138 in leakage power (mW) for C90g and C45soi. The example shown in the graph 100 of FIG. 5 is of conventional spare cells that are connected to Vss and Vdd but not functionally connected with the base cell logic after metallization. This is typical of conventional standard cell libraries or typical ASIC design with unconnected spare cells; the spare cells remain connected to the power source. FIG. 6 is a bar graph illustrating the general leakage trend and the leakage contribution of spare cells in total leakage of the chip.

Additionally, there is a demand for higher performance ASIC designs to add high speed (lower vt) (LOVT) spare cells and shorter turn-around time for system on chip (SOC) development. Since conventional designs are not stable until relatively late in the design cycle, more spare cells are required in the design to ensure adequate choice for selection of spare cells for ECO implementation. Additionally, the limitations of conventional standard cell libraries include the constant leakage current paths. This leakage of functionally unused spare cells that remain connected to the power source increases in magnitude as the demand for the number of spare cells increases, which results in overhead on the cell design and reduces the choice of cell sets for spare modules. This also reduces the spare cell density in the design. In traditional ASIC cell based designs, it is proving more difficult to implement ECO and close timing of timing critical paths. The conventional standard spare cells used for repair constantly consume leakage current. The spare cells in traditional standard cell libraries continue to consume leakage current even if the spare cells are not used functionally. This all contributes to increasing power consumption in the conventional spare cell library designs.

There is a demand in the industry to increase the density of functional base logic cells. There is also a demand to increase the density of interspersed spare cells that form the spare library to improve interconnectivity and functionality choices. However, with the ever increasing density of cells, has come the even more dramatic increase in the overall power consumption. Each cell whether a functional logic base cell or spare cell contributes to the overall power consumption of the ASIC. Each cell of the ASIC, whether functional, functionally unconnected spare cell or functionally connected spare cell, is connected to ground and power within conventional ASIC layout design. Every spare cell, even the spare cells that remain unconnected to the functional logic base cell and do not become part of the working functionality of the ASIC, are connected to ground and power before and after the metallization process which contribute to the overall power consumption of the ASIC. There is an emphasis in ASIC layout design to reduce power consumption of the ever increasing power intensive ASIC.

Thus, there is a need for a cell based design layout of an integrated circuit and corresponding method that addresses the problems of conventional standard spare cells in ASIC layout design. In particular, there is a need to reduce power consumption in conventional cell based design layout of integrated circuits.

### BRIEF DESCRIPTION OF THE DRAWINGS

In order that embodiments of the invention may be fully and more clearly understood by way of non-limitative examples, the following description is taken in conjunction with the accompanying drawings in which like reference numerals designate similar or corresponding elements, regions and portions, and in which:

FIG. 1 is a schematic diagram of a cell with Vdd disconnected from the source of a PMOS transistor and with Vss disconnected from the source of a NMOS transistor in accordance with an embodiment of the invention;

FIGS. 2A and 2B show a library schematic and layout Vdd disconnected from the source of a PMOS transistor and with Vss disconnected from the source of a NMOS transistor of two spare cells in accordance with an embodiment of the invention;

FIGS. 3A and 3B show the library cell layout design of FIGS. 2A and 2B after interconnection of spare cells after the metallization process and after engineering change order (ECO) when a spare cell is interconnected to the base logic cells with Vdd connected from the source of a PMOS transistor and with Vss connected from the source of a NMOS transistor in accordance with an embodiment of the invention;

FIG. 4 shows pins cut at reduced spacing for a metal layer in accordance with an embodiment of the invention;

FIG. 5 is a flow chart of a method in accordance with an embodiment of the invention; and

FIG. 6 is a graph of the leakage trend and leakage contribution of interconnected Vss and Vdd spare cells that are not functionally connected to the base cells of a conventional ASIC layout design in total leakage of the chip.

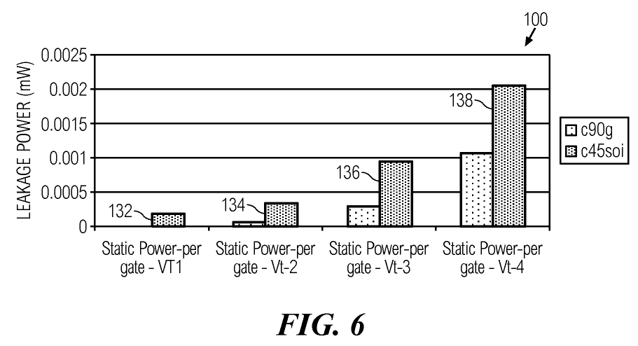

### DETAILED DESCRIPTION OF EMBODIMENTS OF THE INVENTION

An aspect of the invention provides a cell based design layout of an integrated circuit having a function, the layout comprising a plurality of cell based base logic cells each having interconnected transistors to perform a logic function; a plurality of additional cells each having at least one transistor and having the power source unconnected to the additional cell, and the plurality of additional cells functionally unconnected to the plurality of base logic cells.

In an embodiment the at least one additional cell of the plurality of additional cells may have the power source interconnected to the additional cell, and the at least one additional cell may be functionally interconnected to the base logic cells. The additional cell may have at least one transistor having the source unconnected to the power supplies Vss and Vdd, and is functionally unconnected to the plurality of base logic cells. An additional cell may have the source of the at least one transistor interconnected with the power supplies Vss and Vdd. The additional cell may be a NAND, NOR, flip-flop, inverter, or the like. The additional cell could also implement any other functionality. The integrated circuit may be an application specific integrated circuit (ASIC). The additional cell may comprise pins that are unconnected to the power source of the integrated circuit. The pins may be arranged with the distance minimized between the pins and the power source of integrated circuit. The pins of the additional cell may be interconnected with the power source of the integrated circuit. The integrated circuit may have undergone a metallization process.

An aspect of the invention is a method of fabricating a cell based design layout of an integrated circuit having a function and capable of undergoing repair, modification or enhancement of the integrated circuit, the layout comprises fabricating a plurality of interconnected cell based base logic cells having transistors to perform a logic function, and a plurality of additional cells each additional cell having at least one transistor and having the power source unconnected to the additional cell, and the plurality of additional cells functionally unconnected to the plurality of base logic cells.

In an embodiment, the method may further comprise selecting at least one additional cell of the plurality of additional cells, interconnecting the at least one additional cell to the power source and functionally interconnecting the at least one additional cell to a base logic cell within the plurality of base logic cells. The method may further comprise selecting an additional cell, wherein the at least one additional cell has at least one transistor, interconnecting the source of the transistor to the power supplies Vss and Vdd, and interconnecting the additional cell to at least one base logic cell of the plurality of base logic cells. The additional cell may be a NAND, NOR, flip-flop, inverter or the like. The additional cell could also implement any other functionality. The integrated circuit may be an application specific integrated circuit (ASIC). The method may further comprise forming pins on at least one of the additional cells, the pins being unconnected to the power source of the integrated circuit and the pins are arranged with the distance minimized between the pins and the power source of integrated circuit. The method may further comprise selecting the at least one additional cell and interconnecting the pins of the additional cell with the power source of the integrated circuit. The method may further comprise verifying and validating the base cells before or after metallization and selecting at least one additional cell interconnecting with the base logic cells. The method may further comprise verifying and validating the additional cell after interconnection with the power source and the base logic cells. The integrated circuit may undergo repair, modification or enhancement after a metallization process.

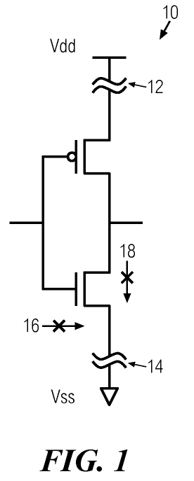

In accordance with an embodiment of the invention, FIG. 1 shows a cell layout of an additional cell that may form part of a spare cell library in ASIC layout design. The additional cell 10 has Vdd disconnected 12 from source of PMOS and with Vss disconnected 14 from source of NMOS in accordance with an embodiment of the invention. With such a configuration there is no gate leakage 16 and no sub threshold leakage 18 of the cell after metallization of the ASIC. In order to differentiate from traditional spare cells in ASIC design layout, the cells 10 described in accordance with the invention are called additional cells that have the power source unconnected to the additional cell.

In traditional design flow, after metallization of an ASIC, conventional spare cells are functionally not connected to the base logic cells, however, the spare cells remain connected to the power source. During ECO, spare cells are selected and functionally interconnected to the base logic cells while the selected spare cells remain connected to the power source.

In the design flow in accordance with an embodiment of the invention, the additional cell 10 serves the same function as conventional spare cells, however, before and after metallization the additional cell is not connected to the power source. During ECO, once selected, an additional cell is connected to the power source and with the base logic cells of the ASIC. The selected additional cells are selected as spare cells and used to repair, enhance, or modify an existing functional logic of the base logic cells. Not all the additional cells within the ASIC design are selected for ECO. The unselected additional cells remain unconnected to the power source. The unselected additional cells that form part of the ASIC design are not used to realize the intended logic or working functionality of the ASIC.

Thus, after ECO, the selected additional cells are connected with the base logic cells and connected to the power source, while the unselected additional cells remain unconnected functionally to the base logic cells. and remain unconnected functionally from the base logic cells.

In all of the selected additional cells that are used to implement an ECO, the source of the PMOS and NMOS transistors are always connected to Vdd and Vss. As the unselected additional cells remain unconnected to the power source, there is no leakage through Vdd or Vss, and there is no gate leakage 16 in the unselected additional cells. As there is no sub-threshold leakage 18 there is reduced dissipated leakage power. During ECO inputs and outputs of the additional cells are configured accordingly to realize the required logic implementation. With the ever increasing emphasis on reducing power, a cell library having the additional cell configuration significantly reduces power consumption.

Additionally, higher performance demands mandate to add high speed (lower vt) (LOVT) additional cells or spare cells and shorter turn-around time for system on chip (SOC) development. Since designs are not stable until relatively late in the design cycle, more spare cells are required in the design to ensure adequate choice for selection of spare cells for ECO implementation. Additionally, the limitations of conventional standard cell libraries include the constant leakage current paths. This leakage of unconnected spare cells increases in magnitude as the demand for the number of spare cells increases. This results in an overhead on the cell design and reduces the choice of cell sets for spare modules. This also reduces the spare cell density in the design. In traditional ASIC cell based designs, it is proving more difficult to implement ECO and close timing of timing critical paths. The conventional standard cell libraries, standard cells are used to implement spare cells. Spare cells are used for repair and in such arrangements constantly consume leakage current. The spare cells in traditional standard cell libraries continue to consume leakage current even if the spare cells are not used functionally. This all contributes to increasing power consumption in the conventional spare cell library designs.

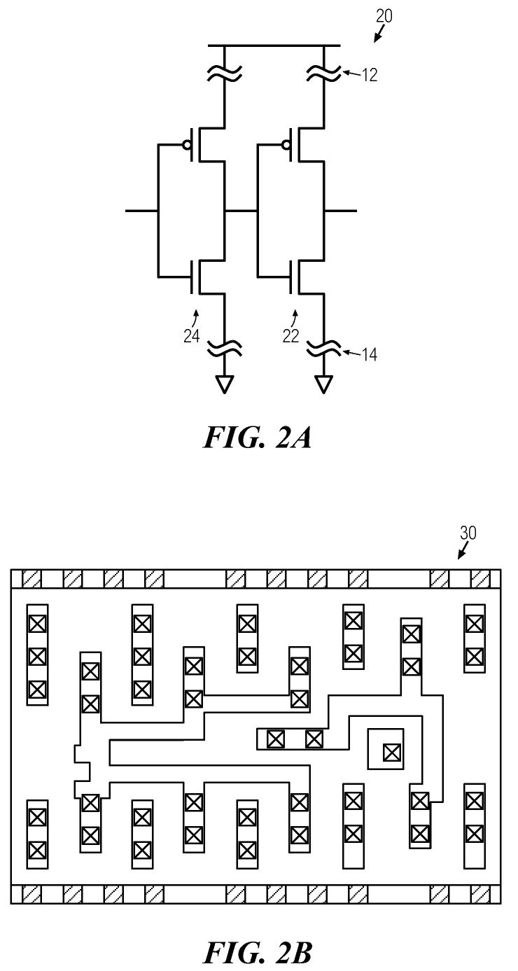

The additional cell or spare cell schematic configuration in accordance with an embodiment of the invention is shown in FIG. 1. The spare cell library design schematic in accordance with an embodiment of the invention is shown in FIG. 2A with additional cells or spare cells 22, 24. In an embodiment, each additional cell 22,24 has a configuration with Vdd and Vss not connected after metallization. For the purpose of this discussion of embodiments of the invention, additional cells are cells that form part of the design of the ASIC, however, additional cells remain floating with respect to the power source until the additional cell is selected for interconnecting with the base logic cells during the ECO process. Such a configuration results in no leakage path through Vdd or Vss, thus there is no gate leakage and no sub threshold leakage. An arrangement 30 in accordance with an embodiment of the invention of the spare cell library showing the unconnected spare cell library 20 after metallization is shown in FIG. 2B. The embodiments of the invention as shown in FIGS. 2A and 2B show library cell design 20 with no leakage path through Vss 14 and Vdd 12. There is no sub threshold leakage 18 and no gate leakage 16 with this configuration where the source of the PMOS and NMOS are kept floating and not connected to Vdd and/or Vss.

In an embodiment of the invention, the cells of FIG. 1 and FIG. 2A may comprise a plurality of cells to form a library, where the plurality of additional cells are used as conventional spare cells. However, in the additional cells, Vdd is disconnected from the source of the PMOS and the Vss is disconnected from the source of the NMOS.

Such an arrangement of the additional cell having the source remain floating, i.e. not connected to Vdd and Vss, cuts off the leakage path for both PMOS and NMOS and reduces the leakage current to practically zero. Advantageously, these additional cells may be selected as conventional spare cells during ECO, however, require to be connected to the power source in accordance with embodiments of the invention. The additional cells selected as spare cells can be functionally interconnected with the base logic cells, and can replace standard library cells without any design implication or overhead.

In an embodiment of the invention, the cell library having additional cell configurations may be used for spare cells insertion in circuit layout design. For example in CMOS library design the devices, for example PMOS and NMOS, have their sources disconnected from power supplies (Vdd and Vss). The additional cells may be used as “spare cells” in the design flow where required. When inserted in the design flow, the functionality of the cells is realized by programming the connectivity of the inputs and outputs according to the intended logic. Power pins of the additional cells may be connected to the power supplies.

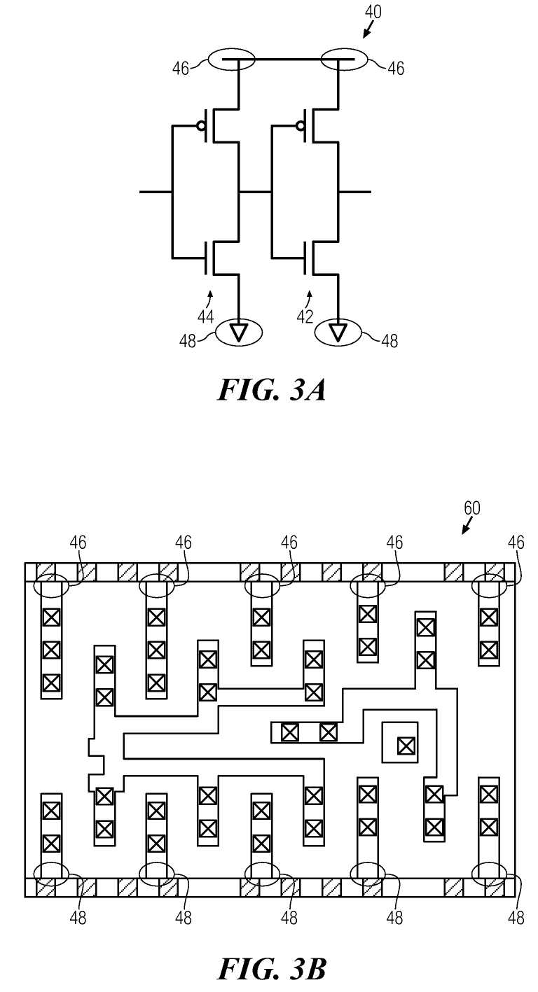

FIGS. 3A and 3B show the library cell layout design 40 of FIGS. 2A and 2B after connection of additional cells after the ECO process with Vdd connected 46 from source of PMOS and with Vss connected 48 from source of NMOS in accordance with an embodiment of the invention. In this embodiment a first additional spare cell 42 and a second additional spare cell 44 are interconnected after the metallization process during ECO to form part of the base cell logic functionality of the ASIC. The arrangement 60 in accordance with an embodiment of the invention of the spare cell library showing the interconnected spare cell library 40 after interconnect after metallization is shown in FIG. 2B. The embodiments of the invention as shown in FIGS. 3A and 3B show the library cell layout design 40.

It will be appreciated that other additional cells (not shown in FIGS. 3A and 3B) are not selected and are not interconnected with the base cells and continue with the configuration of the additional cell arrangement remaining unconnected to the power source with no leakage path through Vss 14 and Vdd 12. Thus, with these non-selected additional cells, there continues to be no sub-threshold leakage 18 and no gate leakage 16. With this configuration of the unconnected additional cells after ECO, the source of the PMOS and NMOS transistors are kept floating and not connected to Vdd and/or Vss as shown in FIGS. 1, 2A and 2B.

In this embodiment, a significant advantage includes the reduced leakage power resulting from the additional cell layout design unconnected power source configuration. In this embodiment the leakage power of the spare cells is reduced to practically zero. High performances cells, each as lower vt (LOVT) cell sets, may be used as additional cells, which may for example be used more effectively while implementing metal ECO.

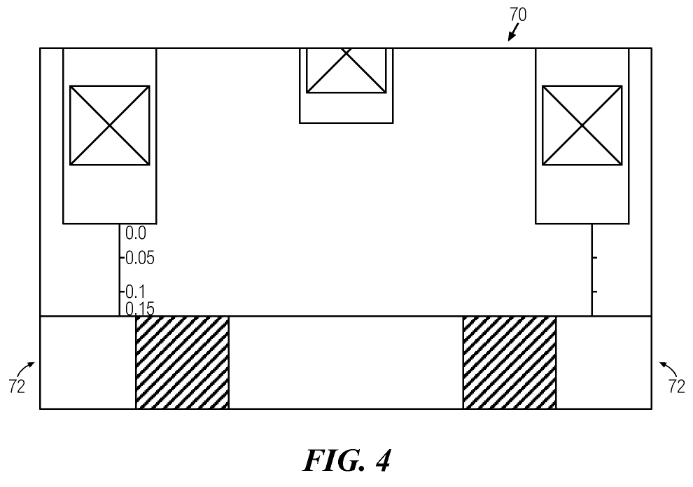

FIG. 4 shows a portion 70 of FIG. 2B in more detail with pins 72 cut at reduced spacing for a metal layer in accordance with an embodiment of the invention to ensure that Vss and Vdd are not interconnected after metallization. Interconnection of the Vss and Vdd is facilitated with the minimum spacing arrangement shown in FIG. 4, such as for example in this embodiment shown the distance is in the region of 0.15 um. With this configuration, the distance required of the interconnect to interconnect the spare cell is minimized, which also satisfies the design rule check (DRC).

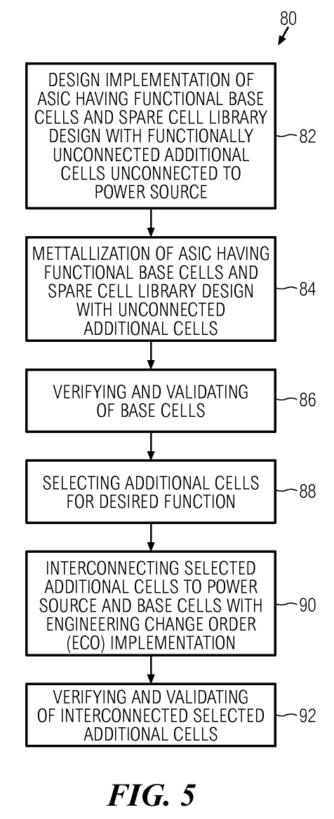

In an embodiment, the additional cell library is implemented by developing the library as shown in the flow chart 80 of FIG. 5 relating to developing the library 62. The generation of the cell layout is generated 64 and the generation of the cell SPICE is generated. For example, the SPICE commands for an additional cell in accordance with an embodiment of the invention may be for example:

.SUBCKT buf_hivt_12_spare a vss vdd x
** N = 18 EP = 4 IP = 0 FDC = 16
M0 x 1 6 vdd PHVT L = 0.1 W = 0.88
M1 8 1 x vdd PHVT L = 0.1 W = 0.88
M2 x 1 8 vdd PHVT L = 0.1 W = 0.88
M3 10 1 x vdd PHVT L = 0.1 W = 0.88
M4 x 1 10 vdd PHVT L = 0.1 W = 0.88
M5 13 1 x vdd PHVT L = 0.1 W = 0.88
M6 1 a 13 vdd PHVT L = 0.1 W = 0.61
M7 15 a 1 vdd PHVT L = 0.1 W = 0.61
M8 x 1 5 vss NHVT L = 0.1 W = 0.63
M9 7 1 x vss NHVT L = 0.1 W = 0.63
M10 x 1 7 vss NHVT L = 0.1 W = 0.63
M11 9 1 x vss NHVT L = 0.1 W = 0.63
M12 x 1 9 vss NHVT L = 0.1 W = 0.63
M13 12 1 x vss NHVT L = 0.1 W = 0.63
M14 1 a 12 vss NHVT L = 0.1 W = 0.46
M15 14 a 1 vss NHVT L = 0.1 W = 0.46
.ENDS buf_hivt_12_spare

Of course, it will be appreciated that other SPICE commands may be realized to generate the additional cell configuration in accordance with an embodiment of the invention.

In FIG. 5, a flow chart 80 is shown of an implementation method in accordance with an embodiment of the invention. The design implementation of the ASIC is designed 82 having functional base cells and additional cells forming the spare cell library design with additional cells that are unconnected to the power source, i.e. Vss and Vdd, and are also unconnected functionally to the functional base cells. The ASIC under goes metallization 84 and the base cells are only interconnected functionally with other base cells, while the additional cells remain unconnected functionally to the base cells and also remain unconnected to Vss and Vdd. The base cells are verified and validated 86 after metallization. Once a repair, enhancement or modification is required, an additional cell is selected 88 from the spare cell library. During ECO, the selected additional cell is selected for the desired function, and the additional cell is interconnected 90 functionally to the base cells and Vss and Vdd. After ECO, the functionality of the ASIC includes the interconnected additional cells and the functionality of the ASIC of each base cell and interconnected additional cell is verified and validated 92.

Embodiments of the invention may be implemented for all SOC applications, in particular in sub-micron technologies. Embodiments reduce the overall leakage power significantly over conventional designs. Embodiments also increase the flexibility and possibility to implement metal ECOs, which enables reduction in time to market. For example, embodiments of the invention may allow ECOs to be made relatively late in the design cycle. Overhead of ECO implementation is also reduced, and subsequent timing closure is facilitated.

While embodiments of the invention have been described and illustrated, it will be understood by those skilled in the technology concerned that many variations or modifications in details of design or construction may be made without departing from the present invention.

1. A cell based design layout of an integrated circuit that performs a logic function, wherein the integrated circuit includes at least a first power supply Vss and a second power supply Vdd, the layout comprising;
a plurality of cell based base logic cells each having interconnected transistors to perform the logic function; and
a plurality of additional cells each having at least one transistor, wherein the plurality of additional cells are unconnected to the first and second power supplies Vss and Vdd and functionally unconnected to the plurality of base logic cells.

2. The cell based design layout of claim 1, wherein at least one additional cell of the plurality of additional cells is functionally connected to the base logic cells and is connected to the first and second power sources Vss and Vdd.

3. The cell based design layout of claim 1, wherein the at least one transistor of at least one of the additional cells of the plurality of additional cells has a source unconnected to the first and second power supplies Vss and Vdd, and functionally unconnected to the plurality of base logic cells.

4. The cell based design layout of claim 1, wherein at least one additional cell of the plurality of additional cells is a NAND, NOR, flip-flop, or inverter.

5. The cell based design layout of claim 1, wherein the integrated circuit is an application specific integrated circuit (ASIC).

6. The cell based design layout of claim 1, wherein at least one additional cell of the plurality of additional cells comprises pins that are unconnected to the first and second power supplies Vss and Vdd of the integrated circuit.

7. The cell based design layout of claim 6, wherein the pins are arranged with the distance minimized between the pins and the first and second power sources of the integrated circuit.

8. The cell based design layout of claim 1, wherein at least one additional cell of the plurality of additional cells comprises pins that are connected with the first and second power supplies of the integrated circuit.

9. The cell based design layout of claim 1, wherein the integrated circuit has undergone metallization.

10. A method of fabricating a cell based design layout of an integrated circuit capable of performing a logic function, wherein the integrated circuit is capable of undergoing repair, modification or enhancement, and wherein the integrated circuit has at least one power source, the method comprising the steps of:
fabricating a plurality of interconnected cell based base logic cells having transistors to perform the logic function; and
fabricating a plurality of additional cells each additional cell having at least one transistor, wherein the power source of the integrated circuit is unconnected to the additional cell, and the plurality of additional cells are functionally unconnected to the plurality of base logic cells.

11. The method of fabricating a cell based design layout of an integrated circuit of claim 10, further comprising:
selecting at least one additional cell of the plurality of additional cells;
connecting the at least one additional cell to the power source; and
functionally connecting the at least one additional cell to a base logic cell of the plurality of base logic cells.

12. The method of fabricating a cell based design layout of an integrated circuit of claim 11, further comprising verifying and validating the at least one additional cell after interconnection with the power source and the base logic cells.

13. The method of fabricating a cell based design layout of an integrated circuit of claim 11, wherein the at least one power source of the integrated circuit comprises a first power source Vss and a second power source Vdd, the method further comprising:
selecting at least one additional cell of the plurality of additional cells, wherein the at least one additional cell has at least one transistor;
connecting the source of the transistor to the first and second power supplies Vss and Vdd; and
connecting the at least one additional cell to at least one base logic cell of the plurality of base logic cells.

14. The method of claim 13, further comprising verifying and validating the at least one additional cell after interconnection with the power source and the base logic cells.

15. The method of fabricating a cell based design layout of an integrated circuit of claim 10, wherein at least one additional cell in the plurality of additional cells is a NAND, NOR, flip-flop, or inverter.

16. The method of fabricating a cell based design layout of an integrated circuit of claim 10, wherein the integrated circuit is an application specific integrated circuit (ASIC).

17. The method of fabricating a cell based design layout of an integrated circuit of claim 10, further comprising forming pins on at least one of the additional cells, the pins being unconnected to the power source of the integrated circuit and wherein a distance between the pins and the power source of integrated circuit is minimized.

18. The method of fabricating a cell based design layout of an integrated circuit of claim 17, further comprising selecting the at least one additional cell and interconnecting the pins of the at least one additional cell with the power source of the integrated circuit.

19. The method of fabricating a cell based design layout of an integrated circuit of claim 10, further comprising verifying and validating the base cells and selecting at least one additional cell of the plurality of additional cells for interconnecting with the base logic cells.

20. The method of fabricating a cell based design layout of an integrated circuit of claim 10, wherein the integrated circuit undergoes repair, modification or enhancement after a metallization process.
